(19) United States
(12) Patent Application Publication
(10) Pub. No.: US 2020/0137273 A1
(43) Pub. Date: Apr. 30, 2020

(54) TEMPERATURE-INDIFFERENT LENS MODULE WITH DEPTH-PERCEPTION FUNCTION AND ELECTRONIC DEVICE USING THE SAME

(71) Applicant: TRIPLE WIN TECHNOLOGY(SHENZHEN) CO.LTD., Shenzhen (CN)

(72) Inventors: SHENG-JIE DING, Shenzhen (CN); SHIN-WEN CHEN, Tu-Cheng (TW); JING-WEI LI, Shenzhen (CN); JIAN-CHAO SONG, Shenzhen (CN)

(21) Appl. No.: 16/455,911

(22) Filed: Jun. 28, 2019

(30) Foreign Application Priority Data
Oct. 31, 2018 (CN) 201811290391.X

(51) Int. Cl. H04N 5/225; H05K 1/18

(52) U.S. Cl. CPC H04N 5/2254; H05K 1/181; H04N 5/2256; H04N 5/2253; H05K 2201/09063; H04N 9/04; H05K 2201/10151; H05K 2201/10257; H05K 2201/10537; H05K 2201/066; H05K 2201/10121

(57) ABSTRACT

A depth-perceiving lens module with enhanced heat-dissipating properties comprises a circuit board, an infrared emitter, and an infrared receiver. The circuit board is provided with at least one positioning hole. The infrared emitter is detachably disposed on a side of the circuit board and electrically connected to the circuit board, the infrared emitter comprises a mounting body and an emitting body. The mounting body wraps at least part of the emitting body, at least part of the mounting body is disposed in the positioning hole and fixed to the circuit board. The infrared receiver is detachably disposed on one side of the circuit board and electrically connected to the circuit board, to receive the reflection of the infrared light from the light emitter.

### FIELD

The subject matter relates to cameras, and in particular, to a lens module and electronic device using the lens module.

### BACKGROUND

Many electronic devices include lens module. The lens module may include a circuit board and a lens fixed on the circuit board by soldering or gluing. However, the lens may be tilted relative to the circuit board due to tolerances in manufacturing process, which lowers the imaging quality. A low connecting strength between the lens and the circuit board may allow the lens to disengage from the circuit board under an external impact. Furthermore, the depth-perceiving lens module needs to be driven by electric power. Heat is generated inside the lens module during the driving process. If the temperature is too high, the lens may be deformed, which further lowers the imaging quality.

Therefore, there is room for improvement in the art.

### BRIEF DESCRIPTION OF THE DRAWINGS

Implementations of the present disclosure will now be described, by way of embodiments only, with reference to the attached figures.

FIG. 1 is a perspective view of a lens module according to a first embodiment of the present disclosure.

FIG. 2 is an exploded perspective view of the lens module of FIG. 1.

FIG. 3 is a cross-sectional view along a line II-II of FIG. 1.

FIG. 4 is a perspective view of a lens module according to a second embodiment of the present disclosure.

FIG. 5 is an exploded perspective view of the lens module of FIG. 4.

FIG. 6 is a cross-sectional view along a line VI-VI of FIG. 4.

FIG. 7 is a perspective view of a lens module according to a third embodiment of the present disclosure.

FIG. 8 is an exploded perspective view of the lens module of FIG. 7.

FIG. 9 is a cross-sectional view along a line IX-IX of FIG. 7.

FIG. 10 is a schematic diagram of an electronic device including the lens module of the present disclosure.

### DETAILED DESCRIPTION

It will be appreciated that for simplicity and clarity of illustration, where appropriate, reference numerals have been repeated among the different figures to indicate corresponding or analogous components. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

The term “comprising,” when utilized, means “including, but not necessarily limited to”; it specifically indicates open-ended inclusion or membership in the so-described combination, group, series, and the like.

### First Embodiment

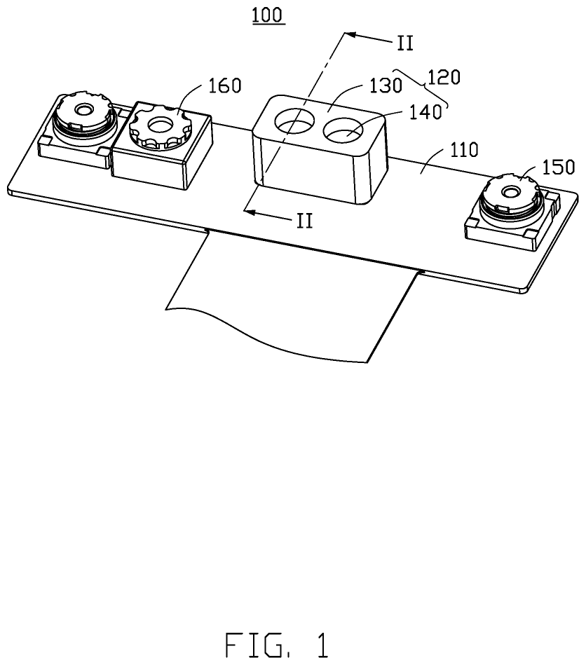

With reference to FIG. 1. A lens module 100 includes a circuit board 110, a light emitter 120, a light receiver 150, and an RGB camera 160. The light emitter 120 is detachably disposed on and electrically connected to the circuit board 110. The light emitter 120 includes a mounting body 130 and an emitting body 140. The emitting body 140 emits light. The mounting body 130 wraps at least a portion of the emitting body 140. The light receiver 150 is detachably disposed on and electrically connected to the circuit board 110. The light receiver 150 receives the reflection of light that is emitted by the light emitter 120. The light emitter 120, the light receiver 150 and the RGB camera 160 are disposed on the same side of the circuit board 110.

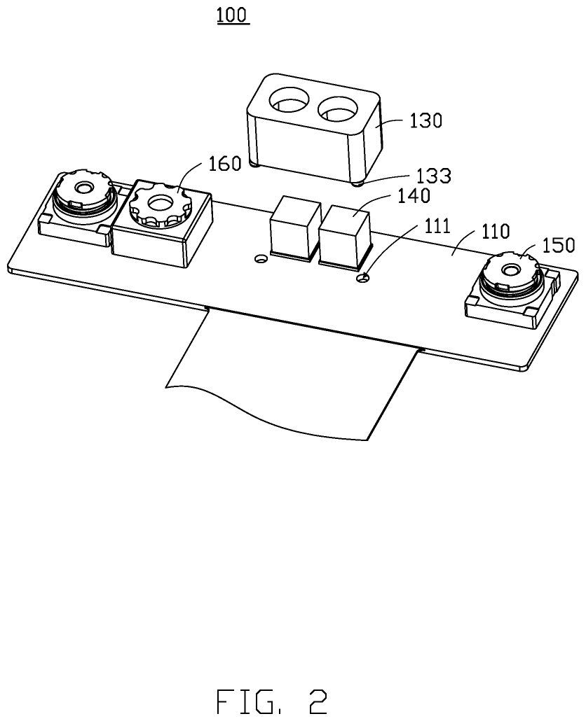

With reference to FIG. 2. The circuit board 110 includes at least one positioning hole 111. The mounting body 130 includes at least one positioning post 133. The mounting body 130 is fixed to the circuit board 110. In one embodiment, there are several positioning holes 111, and the positioning posts 133 match the positioning holes 111 in number, in shape, and in size. The positioning post 133 is detachably disposed in the positioning hole 111. The mounting body 130 and the circuit board 110 are fixed by the positioning hole 111 and the positioning post 133.

The circuit board 110 may be a flexible circuit board, a rigid circuit board, or a rigid-flexible circuit board. The circuit board 110 may also be a single layer circuit board, a double layer circuit board, or a multilayer circuit board. The circuit board 110 includes a plurality of conductive wires (not shown). The light emitter 120, the light receiver 150, and the RGB camera 160 are disposed on and electrically connected to the conductive wires, and communicate with other electronic components through the conductive wires.

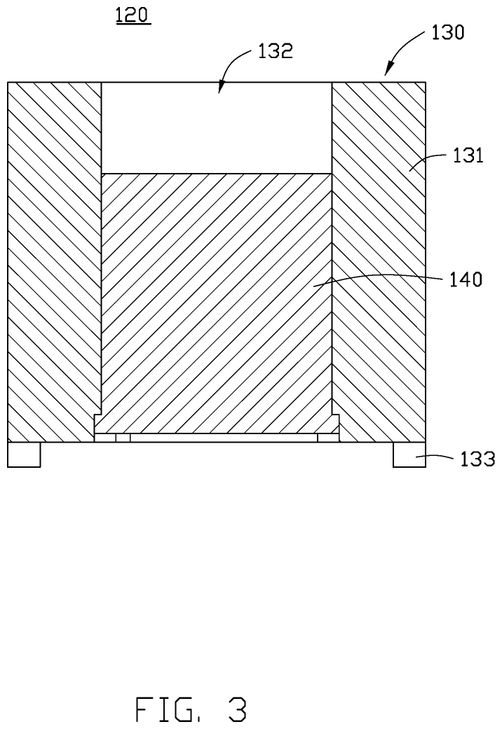

With reference to FIG. 3. The mounting body 130 further includes a main body portion 131 and a through hole 132. The positioning post 133 is connected to the main body portion 131. The through hole 132 extends through the main body portion 131. The emitting body 140 is received in the through hole 132. The mounting body 130 is connected to the circuit board 110 through the positioning post 133 and the positioning hole 111, thereby fixing the emitting body 140 in place inside the mounting body 130. The mounting body 130 has good thermal conductivity, and may made of metal or metal oxide. In one embodiment, the mounting body 130 is a hollow column structure. The main body portion 131 wraps the emitting body 140 to enhance the heat dissipation efficiency of the emitting body 140. The light emitter 120 can be located at a central area of the circuit board 110. The emitting body 140 is a depth camera. The emitting body 140 can emit infrared light towards an external object, and the emitted infrared light is reflected by the object.

The light receiver 150 receives the light reflected from the object. The light receiver 150 converts the received light into an electrical signal and transmits the electrical signal to a central processing unit (not shown). The central processing unit analyzes the electrical signal. In one embodiment, the number of the light receivers 150 may be two. The two light receivers 150 are located at opposite sides of the light emitter 120. The light receiver 150 may be an infrared camera, and the light receiver 150 may sense and receive infrared light.

The RGB camera 160 can be a conventional camera with acquisition and imaging functions. When the RGB camera 160 detects a human face, the RGB camera 160 wakes up the light emitter 120 and the light receiver 150.

### Second Embodiment

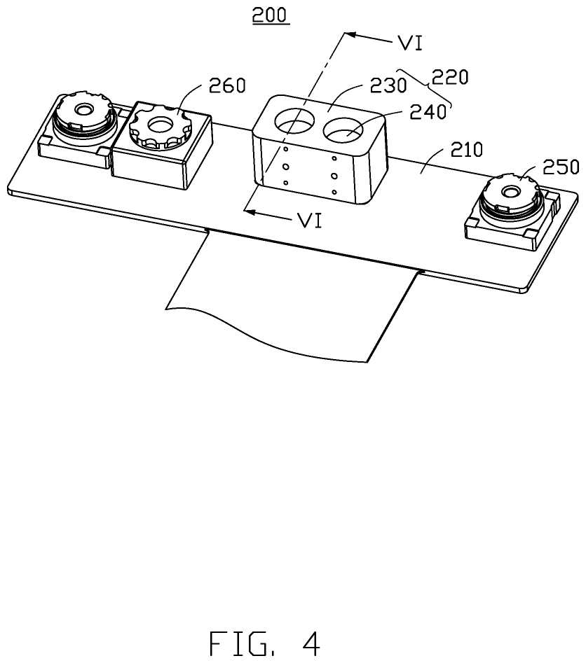

With reference to FIG. 4. A lens module 200 includes a circuit board 210, a light emitter 220, a light receiver 250, and an RGB camera 260. The light emitter 220 is detachably disposed on and electrically connected to the circuit board 210. The light emitter 220 includes a mounting body 230 and an emitting body 240. The emitting body 240 emits light. The mounting body 230 wraps at least a portion of the emitting body 240. The light receiver 250 is detachably disposed on one side of the circuit board 210 and electrically connected to the circuit board 210. The light receiver 250 receives reflection of light that is emitted by the light emitter 220. The light emitter 220, the light receiver 250 and the RGB camera 260 are disposed on the same side of the circuit board 210.

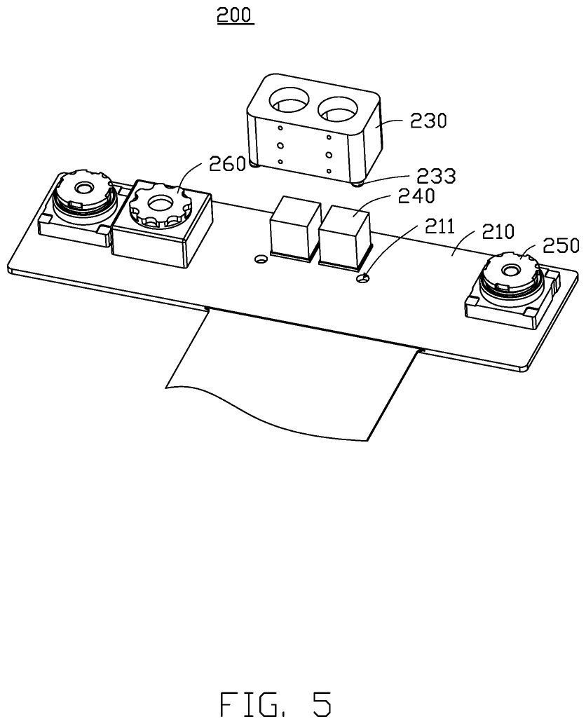

With reference to FIG. 5. The circuit board 210 includes at least one positioning hole 211. The mounting body 230 includes at least one positioning post 233. The mounting body 230 includes at least one positioning post 233. The mounting body 230 is fixed to the circuit board 210. In one embodiment, there are several positioning holes 211, matching the positioning posts 233 in number, in shape, and in size. The positioning post 233 is detachably disposed in the positioning hole 211. The mounting body 230 and the circuit board 210 are fixed by the positioning hole 211 and the positioning post 133.

The circuit board 210 may be a flexible circuit board, a rigid circuit board, or a rigid-flexible circuit board. The circuit board 110 may also be a single layer circuit board, a double layer circuit board, or a multilayer circuit board. The circuit board 210 includes a plurality of conductive wires (not shown). The light emitter 220, the light receiver 250, and the RGB camera 260 are disposed on and electrically connected to the conductive wires, and communicate with other electronic components through the conductive wires.

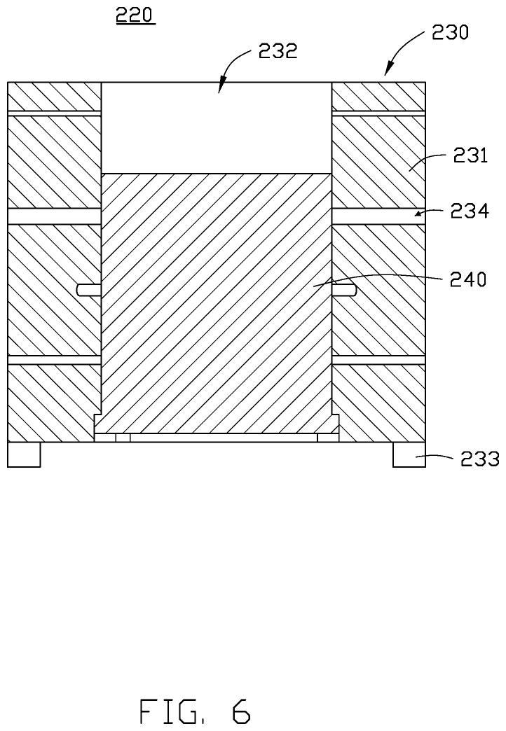

With reference to FIG. 6. The mounting body 230 further includes a main body portion 231 and a through hole 232. The positioning post 233 is connected to the main body portion 231. The through hole 232 extends through the main body portion 231. The emitting body 240 is received in the through hole 232. The mounting body 230 is connected to the circuit board 210 through the positioning post 233 and the positioning hole 211, thereby fixing the emitting body 240 in place inside the mounting body 230. The mounting body 230 has good thermal conductivity, and may made of metal or metal oxide. In one embodiment, the mounting body 230 is a hollow column structure with some hollow grooves in the structure. The mounting body 230 includes a plurality of hollow groove 234. The plurality of hollow groove 234 increases the contact area of the main body portion 231 with the air, thereby improving the heat dissipation efficiency of the mounting body 230. The light emitter 220 can be located at a central area of the circuit board 210. The emitting body 240 is a depth camera. The emitting body 240 can emit infrared light towards an external object, and the emitted infrared light is reflected by the object.

The light receiver 250 receives the light that from the object. The light receiver 250 converts the received light into an electrical signal and transmits the electrical signal to a central processing unit (not shown). The central processing unit analyzes the electrical signal. In one embodiment, the number of the light receivers 250 may be two. The two light receivers 250 are located at opposite sides of the light emitter 220. The light receiver 250 may be an infrared camera, and the light receiver 250 may sense and receive infrared light.

The RGB camera 260 can be a conventional camera with acquisition and imaging functions. When the RGB camera 260 detects a human face, the RGB camera 260 wakes up the light emitter 220 and the light receiver 250.

### Third Embodiment

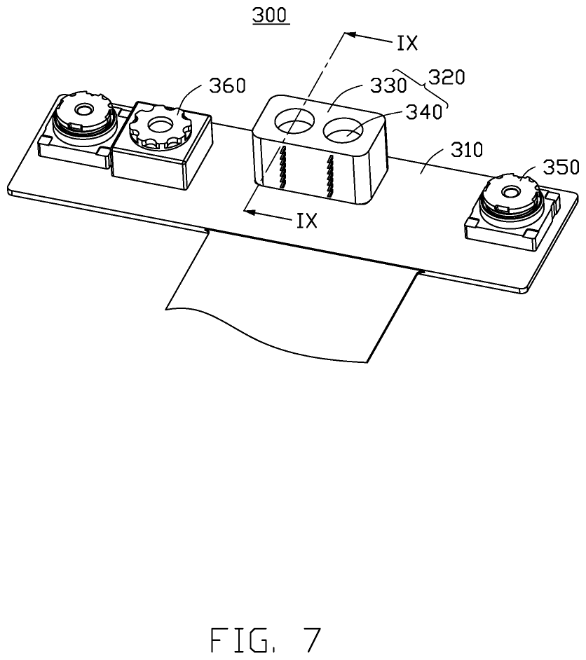

With reference to FIG. 7. A lens module 300 includes a circuit board 310, a light emitter 320, a light receiver 350, and an RGB camera 360. The light emitter 320 is detachably disposed on and electrically connected to the circuit board 310. The light emitter 320 includes a mounting body 330 and an emitting body 340. The emitting body 340 emits light. The mounting body 330 wraps at least a portion of the emitting body 340. The light receiver 350 is detachably disposed on and electrically connected to the circuit board 310. The light receiver 350 receives the reflection of the light emitted by the light emitter 320. The light emitter 120, the light receiver 150 and the RGB camera 160 are disposed on the same side of the circuit board 110.

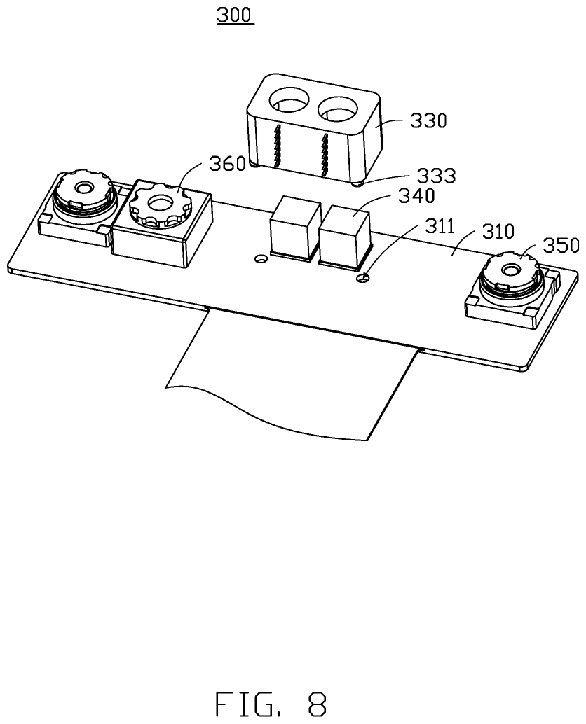

With reference to FIG. 8. The circuit board 310 includes at least one positioning hole 311. The mounting body 330 includes at least one positioning post 333. The mounting body 330 is fixed to the circuit board 310. In one embodiment, there are several positioning holes 311, the positioning posts 333 match the positioning holes 311 in number, in shape, and in size. The positioning post 333 is detachably disposed in the positioning hole 311. The mounting body 330 and the circuit board 310 are fixed by the positioning hole 311 and the positioning post 133.

The circuit board 310 may be a flexible circuit board, a rigid circuit board, or a rigid-flexible combination circuit board. The circuit board 110 may also be a single layer circuit board, a double layer circuit board, or a multilayer circuit board. The circuit board 310 includes a plurality of conductive wires (not shown). The light emitter 320, the light receiver 350, and the RGB camera 360 are disposed on and electrically connected to the conductive wires of the circuit board 310 wires, and communicate with other electronic components through the conductive wires.

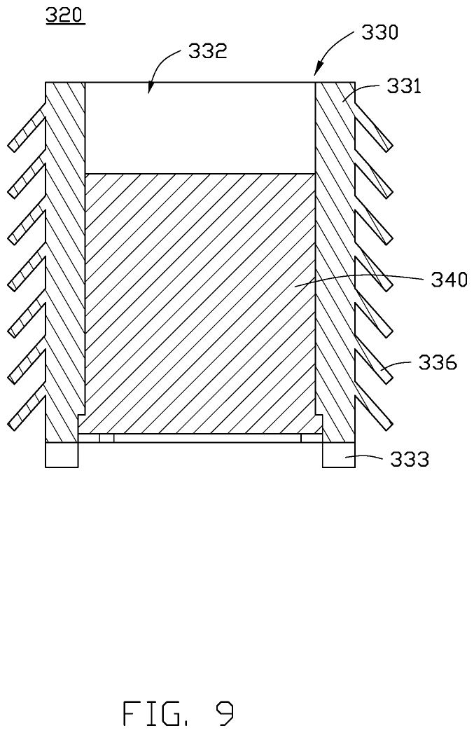

With reference to FIG. 9. The mounting body 330 further includes a main body portion 331 and a through hole 332. The positioning post 333 is connected to the main body portion 331. The through hole 332 extends through the main body portion 331. The emitting body 340 is received in the through hole 332. The mounting body 330 is connected to the circuit board 310 through the positioning post 333 and the positioning hole 311, thereby fixing the emitting body 340 in place inside the mounting body 330. The mounting body 330 has good thermal conductivity, and may made of metal or metal oxide. In one embodiment, the mounting body 330 further includes a plurality of heat dissipating blades 336. The heat dissipating blades 336 extending from the main body portion 331 away from the through hole 332. The heat dissipating blades 336 are each a sheet of material and spaced from each other. The heat dissipating blades 336 increase the contact area of the main body portion 331 with the air, and improve the heat dissipating efficiency of the mounting body 330. The main body portion 331 wraps the emitting body 340 to enhance the heat dissipating effect of the emitting body 340. The light emitter 320 can be located in a central area of the circuit board 310. The emitting body 340 is a depth camera. The emitting body 340 can emit infrared light to scan an external object, and the emitted infrared light is reflected from an object.

The light receiver 350 receives the reflection of the light that emitted by the light emitter 320. The light receiver 350 converts the received light into an electrical signal and transmits the electrical signal to a central processing unit (not shown). The central processing unit analyzes the electrical signal. In one embodiment, the number of the light receivers 350 may be two. The two light receivers 350 are located at opposite sides of the light emitter 320. The light receiver 350 may be an infrared camera, and the light receiver 350 may sense and receive infrared light.

The RGB camera 360 can be a conventional camera with acquisition and imaging functions. When the RGB camera 360 detects a human face, the RGB camera 360 wakes up the light emitter 320 and the light receiver 350.

The lens module of the first to third embodiments enhances the heat dissipation capability of the light emitter by setting the mounting body of the wrapping emitting body. The quality is improved. At least part of the mounting body is disposed in the positioning hole and fixed to the circuit board, thereby enhancing the fixing strength of the light emitter and the circuit board, thereby increasing the robustness.

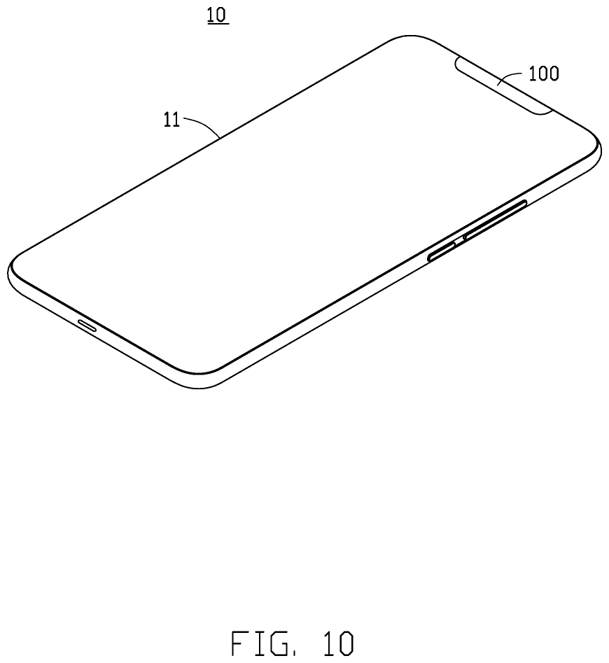

FIG. 10 is a perspective view of an electronic device 10 including a housing 11 and the lens module 100 disposed in the housing 11. The lens module 100 can be any lens module of the first to third embodiments. With reference to FIG. 10, the electronic device 10 is a mobile phone. In other embodiments, the electronic device 10 may also be a personal computer, a smart home appliance, an industrial controller, or the like. When the electronic device 10 is a mobile phone, the lens module 100 can be a front camera and a face recognition unit of the mobile phone.

The embodiments shown and described above are only examples. Therefore, many commonly-known features and details are neither shown nor described. Even though numerous characteristics and advantages of the present technology have been set forth in the foregoing description, together with details of the structure and function of the present disclosure, the disclosure is illustrative only, and changes may be made in the detail, including in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. A lens module, comprising:
a circuit board defining at least one positioning hole;
a light emitter detachably disposed on and electrically connected to the circuit board, wherein the light emitter comprises a mounting body and an emitting body, the emitting body emits light, the mounting body wraps at least part of the emitting body, the at least part of the mounting body is disposed in the positioning hole and fixed to the circuit board; and
a light receiver detachably disposed on and electrically connected to the circuit board, wherein the light receiver receives the reflected light emitted by the light emitter.

2. The lens module of claim 1, wherein the mounting body comprises at least one positioning post, the positioning post matches the positioning hole, and the positioning post is detachable fixed in the positioning hole.

3. The lens module of claim 2, wherein the mounting body comprises at least one through hole, the through hole penetrates through the mounting body, and the emitting body is received in the through hole.

4. The lens module of claim 3, wherein the mounting body comprises a main body portion, the through hole penetrates through the main body portion, and the positioning post is connected to the main body portion.

5. The lens module of claim 4, wherein the body portion is a hollow column structure.

6. The lens module of claim 4, wherein the main body portion is a hollow column structure with some hollow grooves in the structure, and the main body portion comprises a plurality of hollow grooves.

7. The lens module of claim 4, wherein the main body portion comprises a plurality of heat dissipating pins, and the plurality of heat dissipating pins is located at a side of the main body portion away from the through hole, the plurality of heat dissipating pins is spaced apart from each other.

8. The lens module of claim 1, wherein the mounting body is made of metal or metal oxide.

9. The lens module of claim 1, wherein the lens module further comprises at least one RGB camera, the RGB camera is electrically connected to the circuit board.

10. An electronic device comprising:
a body; and
a lens module disposed in the body, the lens module comprising:
a circuit board defining at least one positioning hole;
a light emitter detachably disposed on and electrically connected to the circuit board, wherein the light emitter comprises a mounting body and an emitting body, the emitting body emits light, the mounting body wraps at least part of the emitting body, the at least part of the mounting body is disposed in the positioning hole and fixed to the circuit board; and
a light receiver detachably disposed on and electrically connected to the circuit board, wherein the light receiver receives the reflected light emitted by the light emitter.

11. The electronic device of claim 10, wherein the mounting body comprises at least one positioning post, the positioning post matches the positioning hole, and the positioning post is detachable fixed in the positioning hole.

12. The electronic device of claim 11, wherein the mounting body comprises at least one through hole, the through hole penetrates through the mounting body, and the emitting body is received in the through hole.

13. The electronic device of claim 12, wherein the mounting body comprises a main body portion, the through hole penetrates through the main body portion, and the positioning post is connected to the main body portion.

14. The electronic device of claim 13, wherein the body portion is a hollow column structure.

15. The electronic device of claim 13, wherein the main body portion is a hollow column structure with some hollow grooves in the structure, and the main body portion comprises a plurality of hollow grooves.

16. The electronic device of claim 13, wherein the main body portion comprises a plurality of heat dissipating pins, and the plurality of heat dissipating pins is located at a side of the main body portion away from the through hole, the plurality of heat dissipating pins is spaced apart from each other.

17. The electronic device of claim 10, wherein the mounting body is made of metal or metal oxide.

18. The electronic device of claim 10, wherein the lens module further comprises at least one RGB camera, the RGB camera is electrically connected to the circuit board.
